(19) United States
(12) Patent Application Publication
(10) Pub. No.: US 2010/0140811 A1
(43) Pub. Date: Jun. 10, 2010

(54) SEMICONDUCTOR DIE INTERCONNECT FORMED BY AEROSOL APPLICATION OF ELECTRICALLY CONDUCTIVE MATERIAL

(75) Inventors: Jeffrey S. Leal, Scotts Valley, CA (US); Scott McGrath, Scotts Valley, CA (US); Suzette K. Pangrle, Cupertino, CA (US)

Correspondence Address: HAYNES BEFFEL & WOLFELD LLP, P O BOX 366, HALF MOON BAY, CA, 94019, US

(73) Assignee: Vertical Circuits, Inc., Scotts Valley, CA (US)

(21) Appl. No.: 12/634,598

(22) Filed: Dec. 9, 2009

Related U.S. Application Data
(60) Provisional application No. 61/121,138, filed on Dec. 9, 2008.
(60) Provisional application No. 61/280,584, filed on Nov. 4, 2009.

(51) Int. Cl. H01L 23/52; H01L 21/50

(52) U.S. Cl. 257/777; 438/107; 257/E21.499; 257/E23.141

(57) ABSTRACT

An interconnect terminal is formed on a semiconductor die by applying an electrically conductive material in an aerosol form, for example by aerosol jet printing. Also, an electrical interconnect between stacked die, or between a die and circuitry in an underlying support such as a package substrate, is formed by applying an electrically conductive material in an aerosol form, in contact with pads on the die or on the die and the substrate, and passing between the respective pads. In some embodiments a fillet is formed at the inside corner formed by an interconnect sidewall of the die and a surface inboard from pads on an underlying feature (underlying die or support); and the electrically conductive material passes over a surface of the fillet.

### CROSS-REFERENCE TO RELATED APPLICATION

This application claims priority from J. Leal, U.S. Provisional Application No. 61/121,138, titled “Semiconductor die interconnect terminal formed by aerosol application of electrically conductive material”, which was filed Dec. 9, 2008, and which is hereby incorporated by reference. This application also claims priority in part from S. McGrath et al. U.S. Provisional Application No. 61/280,584, titled “Stacked die assembly having reduced stress interconnects”, which was filed Nov. 4, 2009, and which is in pertinent part incorporated herein by reference.

### BACKGROUND

This invention relates to electrical interconnection of die in stacked die assemblies.

A typical semiconductor die has a front (“active”) side, in which the integrated circuitry is formed, a back side, and sidewalls. The sidewalls meet the front side at front edges and the back side at back edges. Semiconductor die typically are provided with interconnect pads (die pads) located at the front side for electrical interconnection of the circuitry on the die with other circuitry in the device in which the die is deployed. Some die as provided have die pads on the front side along one or more of the die margins, and these may be referred to as peripheral pad die. Other die as provided have die pads arranged in one or two rows at the front side near the center of the die, and these may be referred to as center pad die. The die may be “rerouted” to provide a suitable arrangement of interconnect pads at or near one or more of the margins of the die (the “interconnect margins”).

Semiconductor die may be electrically connected with other circuitry in a package, for example on a package substrate or on a leadframe, by any of several means. Such z-interconnection may be made, for example, by wire bonds, or by flip chip interconnects, or by tab interconnects. The package substrate or leadframe provides for electrical connection of the package to underlying circuitry (second-level interconnection), such as circuitry on a printed circuit board, in a device in which the package is installed for use.

A number of approaches have been proposed for increasing the density of active semiconductor circuitry in integrated circuit chip packages, while minimizing package size (package footprint, package thickness). In one approach to making a high density package having a smaller footprint, two or more semiconductor die, of the same or different functionality, are stacked one over another and mounted on and connected to a package substrate.

Electrical interconnection of stacked semiconductor die using wire bonds presents a number of challenges. For instance, two or more die in a stack may be mounted on a substrate with their front sides facing away from the substrate, and connected by wire bonds die-to-substrate or die-to-die. Die-to-die wire bond interconnect may be made where an upper die is dimensioned or located so that the upper die does not overlie the margin of the lower die to which it is connected, and so that sufficient horizontal clearance is provided to accommodate the wire bonding tool. If the offset is too narrow, the wire bonding tool may impact and damage the upper die. Additionally, the offset must be wide enough so that the bond wires between the upper die pad and the lower die pad do not touch the upper die edge. Sufficient clearance may be provided where, for example, the footprint of the upper die is sufficiently narrower than the lower die; or, for example, where the upper die is arranged so that the footprint of the upper die is sufficiently offset in relation to the margin of the lower die.

The requirement of sufficient offset to accommodate the bonding tool and wire span limits the dimensions of die that may in practice be stacked in this manner, however. Where the interconnect pads are situated along only one margin of the die, the die may be arranged in a stepwise offset fashion, in which the interconnect margins of all the die are oriented in the same direction, and the interconnect pads on each die are exposed by offsetting the overlying die. The requirement of sufficient offset to accommodate the bonding tool and wire span limits the number of die that may in practice be stacked in this manner, because the footprint of the stack increases significantly as the die count increases.

Alternatively, the die in the stack may be indirectly interconnected by connecting them to a common substrate on which the stack is mounted. Where a lower die in a stack is wire bonded die-to-substrate, and where the footprint of an upper die overlies the margin of the lower die, a spacer may be interposed to provide sufficient vertical clearance between the lower and the upper die to accommodate the wire loops over the lower die. In such a configuration the wire bond die-to-substrate connection of the lower die must be completed before the spacer and the upper die are stacked over it; that is, the die must be stacked in situ on the substrate and the die must be stacked and connected serially.

U.S. Pat. No. 7,245,021 describes a vertically stacked die assembly including a plurality of integrated circuit die electrically interconnected by “vertical conducting elements”. The die are covered with an electrically insulative conformal coating. The vertical conducting elements are formed of an electrically conductive polymer-based material, applied adjacent the edge of the die. The die are provided with metallic conducting elements, each having one end attached to electrical connection points at the die periphery and having the other end embedded in a vertical conducting polymer element. In such a configuration the metallic conducting element or interconnect terminal is bonded to an interconnect pad (die pad), which may be a peripheral die pad in the die as provided, or it may be situated at or near the die periphery as a result of rerouting of the die circuitry. The interconnect terminal extends outwardly beyond the die edge and as such it may be referred to as an “off-die” terminal. The off-die interconnect terminal may be, for example, a wire (formed for example in a wire bond operation) or a tab or ribbon (formed for example in a ribbon bond operation).

Alternatively, the interconnect terminal may be a bump or glob of an electrically conductive polymer material deposited onto the die pad. The glob may be shaped so that it extends toward the die edge, and may extend to the die edge or slightly beyond the die edge (constituting an off-die terminal); it may be in the shape of a thumb, for example. Or, the glob may be formed entirely above the pad. The electrically conductive polymer-based material may be, for example, a curable conductive polymer material such as a conductive epoxy.

As illustrated in U.S. Pat. No. 7,245,021, the die may be arranged in the stack so that the interconnect margins are vertically aligned (hence, the die are “vertically stacked”), and the die sidewalls adjacent the interconnect margins constitute a stack face. Off-die terminals (wire, tab, ribbon, or glob) project at the stack face, making them available for connection by a variety of methods, such as for example using a trace of electrically conductive epoxy applied to the stack face to form a “vertical conducting element”. Where globs of electrically conductive material extend to the stack face, the globs are similarly available for connection by a variety of methods.

In configurations that have off die interconnect terminals, or that have bumps or globs of conductive material on the die pads, the terminals stand above the front side of the die, and adjacent die in the stack are separated by a standoff between the front side of a lower die and the back side of the next overlying die to accommodate the terminals. A spacer may optionally be interposed in the space to support adjacent die; optionally the spacer may be a film adhesive of suitable thickness both to fill the space and to affix the die to one another. The spacer is located or sized (e.g., it is made smaller than the die, or the edge of the spacer is offset to expose the interconnect margin) so that it does not block the interconnect terminals.

It may be preferable to eliminate a need for off-die terminals. Accordingly, the interconnect terminal may be formed in or at the active side of the die, at or near the margin of the die where the active side of the die meets the die sidewall. Such an interconnect terminal at the margin may be a die pad or an extension of a die pad, for example; and it may be situated at or near the die margin as a result of rerouting of the die circuitry. Or, for example, the interconnect terminal may be formed on the die sidewall, and may be connected to the integrated circuitry of the die by attachment of a trace of conductive material to an extension of the die pad, for example, or to rerouting circuitry. Or, for example, the interconnect terminal may be formed so that it wraps around a chamfer at the front side die edge (at the intersection of the die sidewall with active side of the die). Such a wraparound terminal is partly on the chamfer and partly on the die sidewall. A similar wraparound terminal may be formed over the back side die edge (at the intersection of the die sidewall with back side of the die), where no chamfer is present. Or, for example, the interconnect terminal may be formed so that it wraps around a chamfer that is formed at the front side die edge, and further around a chamfer that is formed at the back side die edge. Such a wraparound terminal is partly on the front edge chamfer, and partly on the die sidewall, and partly on the back edge chamfer. In each of these configurations, the interconnect terminal is located at least in part at the stack face and, accordingly, it is available for connection at the stack face by a variety of methods, such as for example using a trace of electrically conductive epoxy applied to the stack face to form a “vertical conducting element”. Examples of various interconnect terminal configurations are illustrated in, for example, S. J. S. McElrea et al. U.S. patent application Ser. No. 12/124,077, titled “Electrically interconnected stacked die assemblies,” which was filed May 20, 2008. Methods for formation of various interconnect terminals at the wafer processing level, or at the die array processing level, are described in, for example, L. D. Andrews, Jr. et al. U.S. patent application Ser. No. 12/143,157, titled “Three-dimensional circuitry formed on integrated circuit device using two-dimensional fabrication,” which was filed Jun. 20, 2008.

As noted above, peripheral pad die, and rerouted die generally, may have interconnect pads arranged at or near one or more of the margins of the die (the “interconnect margins”). Where the interconnect pads are very close to the die edge, and where a space is provided between adjacent die in the stack, interconnection of die may be made by a vertically-oriented interconnect at the stack face, provided that the interconnect intrudes between adjacent die onto the pads. For example, the interconnect material as applied (such as an electrically conductive epoxy) has the ability to flow into the space at the margin between adjacent die, to make electrical connection with pads in the margin at the active side of the die. Interconnection of die by intrusion of flowable, curable interconnect material in the space between die is shown, for example, in T. Caskey et al. U.S. application Ser. No. 12/124,097, titled “Electrical interconnect formed by pulsed dispense”, which was filed May 20, 2008. This necessitates providing a separation between adjacent die sufficient to permit the intrusion.

### SUMMARY

In one general aspect the invention features a method for forming interconnect terminals on a plurality of die, each die having an active side, an interconnect margin and an interconnect sidewall adjacent an interconnect edge and having interconnect pads arranged in the interconnect margin, by: forming a stack of the die in which successive die in the stack are separated by spacers, and in which the die are arranged so that the interconnect sidewalls are situated generally in a plane perpendicular to the plane of the active side of the die and the spacers are offset in relation to the interconnect edges such that at least a portion of the interconnect margin is exposed; and directing an aerosolized conductive material at a jet angle less than 90° and greater than 0° from the plane of the active sides of the die.

Each die overhangs the exposed interconnect margin of an underlying spaced-apart die, and during the deposition the overhang “shadows” the underlying interconnect margin to an extent that depends upon the jet angle and the space between the die. That is, for a given jet angle, where the space is greater the deposition reaches farther inboard on the interconnect margin; and for a given space between die, where the jet angle is less the deposition reaches farther inboard on the interconnect margin. At jet angles approaching 90° (near normal to the active side of the die), the margin becomes nearly completely occluded by the shadow of the overlying die; at jet angles approaching 0° (near normal to the plane of the interconnect walls), little to no material is deposited on the interconnect margins or on the pads. At a jet angle of about 45°, for example, the deposition thickness is expected to be nearly uniform on all the exposed surfaces, and deposition is expected to reach inboard from underlying die edges to a distance approximately equal to the space between the die.

In some embodiments the die may be separated and individually treated. In other embodiments the die and spacers are further treated as a stacked die assembly.

In some embodiments additional die constitute the spacers. In some embodiments the additional die are “dummy” die; in other embodiments the additional die are active die.

In another general aspect the invention features a method for forming interconnect terminals on an assembly of stacked die, each die having an active side, an interconnect margin and an interconnect sidewall adjacent an interconnect edge and having interconnect pads arranged in the interconnect margin, by: forming a stack of the die in which successive die in the stack are separated by spacers, and in which the die are arranged so that the interconnect sidewalls are situated generally in a plane perpendicular to the plane of the active side of the die and the spacers are offset in relation to the interconnect edges such that at least a portion of the interconnect margin is exposed; and directing an aerosolized conductive material at a jet angle less than 90° and greater than 0° from the plane of the active sides of the die.

In some embodiments additional die constitute the spacers. In some embodiments the additional die are “dummy” die; in other embodiments the additional die are active die. In embodiments where the additional die are active die, the additional die may be arranged so that their interconnect sidewalls are situated generally in a plane perpendicular to the plane of the active side of the die, and such that at least a portion of their interconnect margins are exposed; and the additional die may also be provided with interconnect terminals by directing an aerosolized conductive material at a jet angle less than 90° and greater than 0° from the plane of the active sides of the die.

In another general aspect the invention features a method for making an electrically interconnected stacked die assembly, by forming interconnect terminals on an assembly of stacked die, generally as described above, and then applying a trace of an electrically conductive interconnect material to connect interconnect terminals.

In another general aspect the invention features a plurality of die, each die having an active side, an interconnect margin and an interconnect sidewall adjacent an interconnect edge and having an interconnect pad in the interconnect margin, and having an interconnect terminal constituting a line formed from the pad to and over the interconnect edge and over the interconnect sidewall.

In another general aspect the invention features an assembly of stacked die, each die having an active side, an interconnect margin and an interconnect sidewall adjacent an interconnect edge and having interconnect pads arranged in the interconnect margin; the assembly including a stack of the die in which successive die in the stack are separated by spacers, and in which the die are arranged so that the interconnect sidewalls are situated generally in a plane perpendicular to the plane of the active side of the die and the spacers are offset in relation to the interconnect edges; and an interconnect terminal constituting a line formed from interconnect pads to and over the interconnect edge and over the interconnect sidewall.

In another general aspect the invention features electrically interconnected offset die stack assemblies, and methods for interconnecting offset die stack assemblies. According to this aspect, a dielectric material is deposited at the inside angle formed by a die sidewall and an underlying surface to form a fillet; and an interconnect trace is formed passing over the surface of the fillet. The die sidewall can be, for example, the interconnect sidewall of the bottom die; and the underlying surface can be, for example, an area of the die attach side of the substrate, inboard of the bond pads and adjacent the die sidewall. Or, for example, the interconnect sidewall can be the interconnect sidewall of an upper die; and the underlying surface can be, for example, an electrically insulated area of the front side of an underlying die, inboard of the die pads on the underlying die and adjacent the upper die sidewall. Or, for example, the die sidewall can be a sidewall of a flip chip die oriented die-down on the substrate and electrically connected to the substrate in the die footprint, and the underlying surface can be, for example, an electrically insulated area of the die attach side of the substrate, inboard of the bond pads and adjacent the die sidewall. Or, for example, the interconnect sidewall can be the interconnect sidewall of a die stacked over a flip chip die; and the underlying surface can be, for example, an electrically insulated area of the back side of the underlying flip chip die.

The dielectric material may be deposited so that it forms a fillet approximating a right triangular shape in transverse section; viewed in this way the hypotenuse of the triangle shape is a sloping surface over which an interconnect trace can be formed; and a vertical side of the triangle forms an angle with the hypotenuse at or near the upper die interconnect edge. The sloping surface of the fillet may be slightly concave or convex, or may be a more complex slightly curved surface. The sloping surface of the fillet can provide a gradual transition from die-to-die or from die-to-substrate, eliminating abrupt angular (approximately right-angle) transitions at the interconnect edges of the die and at the inside corners where the back edge of the die sidewall meets the underlying surface. In some configurations, a first fillet formed at the sidewall of a bottom die and a substrate can support a first set of electrical interconnect traces connecting pads on the bottom die with bond pads in a first row on the substrate; and an additional fillet formed over the first interconnect traces on the first fillet at the sidewall of an upper die and the bottom die can support a second set of interconnect traces from die pads on the upper die to bond pads in a second row, outboard from the first row, on the substrate.

A dielectric material for the fillet may be selected as having thermal expansion characteristics (particularly, coefficient of thermal expansion, or “CTE”) that approximate or make a compromise between the various CTEs of the various components of the assembly, to help stabilize the assembly, reducing delamination effects. Suitable dielectric materials for the fillet can be deposited in a flowable form and thereafter cured or allowed to cure to form the fillet. Such materials include any of various polymers, particularly organic polymers, and they may include any of a variety of amendment components, such as fillers and the like. Particularly suitable materials include, for example, dielectric underfill materials. Underfill materials are employed commonly in semiconductor packaging applications and, accordingly, they have generally known mechanical, physical, and chemical characteristics from which an acceptable choice for the fillet can be made. They can be applied in a directed manner over a selected area using conventional tools.

The interconnect trace can formed by directing an aerosolized conductive material in a line contacting a first pad, passing over the surface of the fillet, and contacting a second pad to be electrically connected to the first pad. The deposit for an interconnect trace may be made in a single pass of the spray apparatus; or in two or more passes, to increase the amount of material deposited. Where the material is deposited in more than one pass, a cur may be conducted following one or more of the passes and preceding subsequent passes.

The die and assemblies according to the invention can be used in computers, telecommunications equipment, and consumer and industrial electronics devices.

### BRIEF DESCRIPTION OF THE DRAWINGS

FIG. 1A is a diagrammatic sketch in a transverse partial sectional view showing a stack of die.

FIG. 1B is a diagrammatic sketch in a transverse partial sectional view as in FIG. 1A showing a stack of die having interconnect terminals according to an embodiment of the invention.

FIG. 1C is a diagrammatic sketch in transverse partial sectional view as in FIG. 1A showing an interconnected stack of die according to an embodiment of the invention.

FIG. 2 is a diagrammatic sketch in a sectional view showing a portion of an aerosol application tool suitable for use in making die interconnect terminals according to an embodiment of the invention.

FIGS. 3A and 3B are diagrammatic sketches in plan view showing stages in deposition of interconnect material according to an embodiment of the invention.

FIGS. 3D and 3E are diagrammatic sketches in plan view showing stages in deposition of interconnect material according to another embodiment of the invention.

FIG. 3C is a diagrammatic sketch in a transverse sectional view of deposited interconnect material, taken at C-C′ in FIG. 3B.

FIGS. 4A-4C, 5A-5B, 6A-6B are diagrammatic sketches showing stages in depositing interconnect terminal material onto a stack of die according to an embodiment of the invention. FIGS. 4A, 5A, 6A are transverse partial sectional views; FIG. 4B are partial elevational views; and FIG. 4C is a partial plan view.

FIG. 7 is a diagrammatic sketch in a transverse partial sectional view showing stages in depositing interconnect terminal material onto a stack of die according to another embodiment of the invention.

FIG. 8A is a diagrammatic sketch in a transverse partial sectional view showing a stack of die.

FIG. 8B is a diagrammatic sketch in a transverse partial sectional view as in FIG. 8A showing a stack of die having interconnect terminals according to an embodiment of the invention.

FIG. 8C is a diagrammatic sketch in transverse partial sectional view as in FIG. 8A showing an interconnected stack of die according to an embodiment of the invention.

FIG. 9A is a diagrammatic sketch in a plan view showing a stack of die according to another embodiment of the invention.

FIGS. 9B and 9C are a diagrammatic sketches showing another embodiment of an interconnected stacked die assembly in a sectional view as indicated at 9B-9B in FIG. 9A.

FIG. 10A is a diagrammatic sketch in a plan view showing a stack of die according to another embodiment of the invention.

FIGS. 10B and 10C are a diagrammatic sketches showing another embodiment of an interconnected stacked die assembly in a sectional view as indicated at 10B-10B in FIG. 10A.

FIG. 11A, 11B, 11C and 11D illustrate examples of electrically interconnected stacked die assemblies including offset die in a stairstep configuration.

### DETAILED DESCRIPTION

The invention will now be described in further detail by reference to the drawings, which illustrate alternative embodiments of the invention. The drawings are diagrammatic, showing features of the invention and their relation to other features and structures, and are not made to scale. For improved clarity of presentation, in the FIGs. illustrating embodiments of the invention, elements corresponding to elements shown in other drawings are not all particularly renumbered, although they are all readily identifiable in all the FIGs. Also for clarity of presentation certain features are not shown in the FIGs., where not necessary for an understanding of the invention. At some points in the description, terms of relative positions such as “above”, “below”, “upper”, “lower”, “top”, “bottom” and the like may be used, with reference to the orientation of the drawings; such terms are not intended to limit the orientation of the device in use.

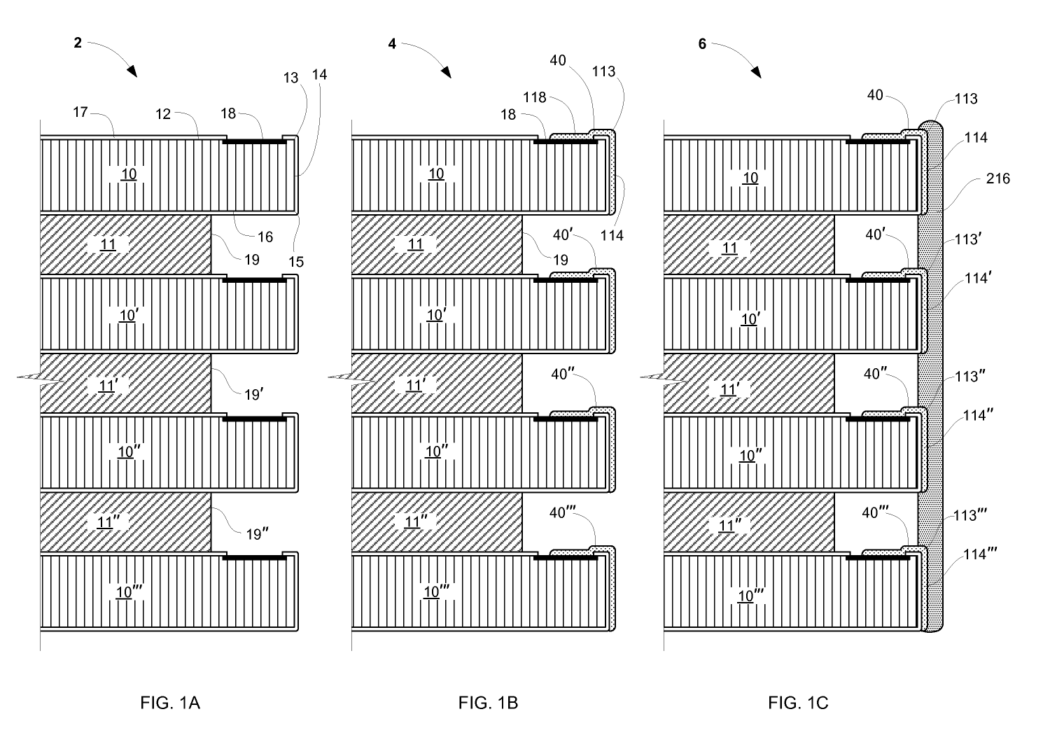

FIGS. 1A-1C illustrate at 2, 4, and 6 progressive stages in interconnection of the die in a stacked die assembly according to an embodiment of the invention. In this example, four die 10, 10′, 10″, 10′″ are stacked over one another. Each die has an active (“front”) side 12, an opposite backside 16, and a sidewall 14. A front side die edge 13 is defined at the intersection of the front side and the die sidewall, and a backside die edge 15 is defined at the intersection of the backside of the die and the die sidewall. Interconnect pads, e.g. 18, are situated at the active side of the die in a margin of the die adjacent the front side die edge; accordingly die margin in which the pads are arranged may be referred to as an “interconnect margin”, the front side die edge may be referred to as an “interconnect edge”, and the die sidewall adjacent the interconnect edge may be referred to as an “interconnect sidewall”. The interconnect pads may be peripheral pads arranged as in the die as provided; or rerouting may have provided for an arrangement of the interconnect pads different from the original arrangement of die pads in the die. Adjacent die in the stack are separated by spacers 11, 11′, 11″, which are dimensioned and arranged so that the spacer walls 19, 19′, 19″, are recessed with respect to the die sidewalls, leaving the die pads 18 uncovered. The die are arranged in the stack so that the interconnect edges are positioned vertically generally (though not necessarily precisely) over one another, and so that the interconnect sidewalls lie generally (though not precisely) in a plane generally perpendicular to the plane of the active side of any one of the die. In the example shown in these FIGs., each die is covered by a conformal electrically insulative coating 17, which may be formed of an organic polymer such as a parylene, for example.

The spacers 11, 11′, 11″ may be, for example, “dummy” die, or an adhesive film. Or, for example, the spacers 11, 11′, 11″ may be additional interposed active die oriented so that their respective interconnect sidewalls project beyond other sidewalls of the die 10, 10′, 10″, 10′″. Such a stack may be referred to as a “staggered stack” of die, and various staggered stack configurations are illustrated in, for example, U.S. patent application Ser. No. 12/124,077, referenced above.

Where the spacers are an adhesive film, the spacers serve to affix the die in the stack. Where the spacers are “dummy” die, or interposed active die, they may be affixed in the stack by an additional adhesive, which may be a die attach adhesive, for example, and which may be dispensed as a liquid or may be applied as a thin adhesive film, for example. Or, where the die are provided with a conformal dielectric polymer coating, the dielectric coating may serve to adhere the die to one another in the stack.

FIG. 1B shows at 4 a stacked die assembly as in FIG. 1A, in which each die has an interconnect terminal 40, 40′, 40″, 40′″, according to the invention. The interconnect terminals are formed of an electrically conductive material, applied in an aerosol according to the invention, as described below. The interconnect terminal makes electrical connection with the surface of the pad 18, and extends from the pad on the electrically insulative coating 17 around the interconnect edge 13 and over the interconnect sidewall 14. Because the material of the interconnect terminal is applied in an aerosol, the interconnect terminal conforms to the surfaces, namely to the die pad, as shown at 118, to the surface of the electrically insulative coating over the interconnect edge, as shown at 113, and on the interconnect sidewall, as shown at 114. In this example, the interconnect terminal does not extend onto the spacer wall 19, 19′, 19″, nor onto the backside of the die outboard from the spacer wall. In other configurations the conductive material may contact the spacer wall. Accordingly, there is no die-to-die electrical continuity between the interconnect terminals on adjacent die.

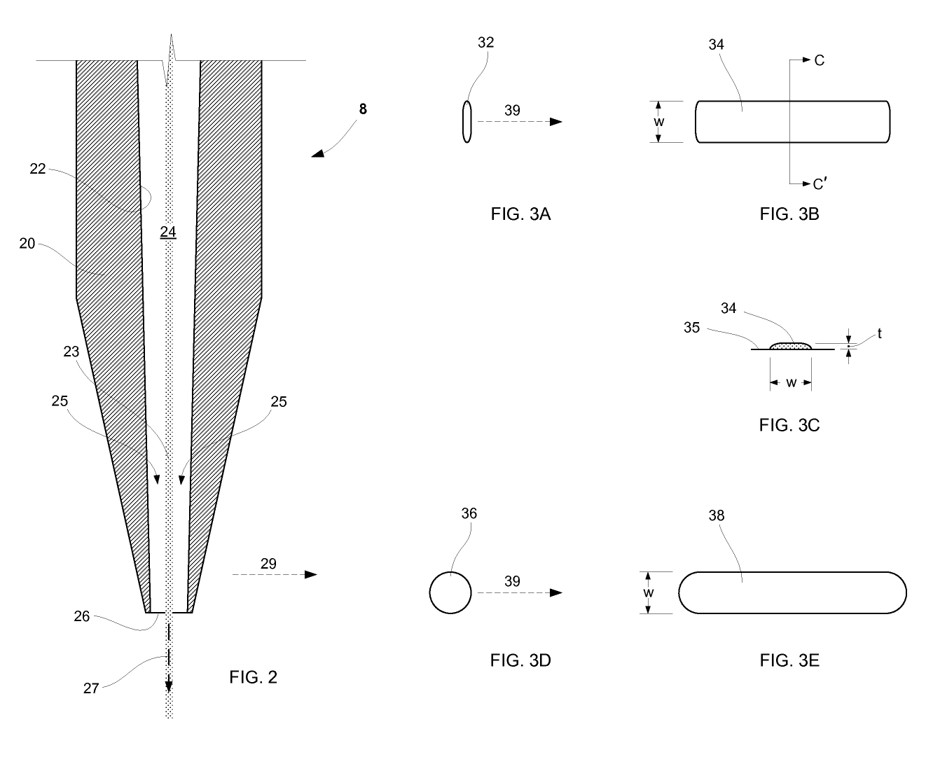

Methods for forming the interconnect terminals are described in more detail below, with reference to FIGS. 2, 3A-3D, 4A-4C, 5, for example. Suitable electrically conductive materials for the interconnect terminals include materials that can be applied in aerosol form, such as a conductive ink, for example any of various nanoparticle inks and the like. The interconnect terminal material may be a curable material. Suitable interconnect materials are supplied, for example, by Five Star Technologies, Independence, Ohio, as the “ElectroSperse” series of inks.

At the stage illustrated in FIG. 1B, the die in the stack are not electrically connected one to another. At this stage, the individual die, each provided with a full set of interconnect terminals, may in some applications be separated at the die-spacer interface and thereafter subjected to subsequent treatment. In such applications the spacers may be discarded following separation; or, the spacers may be left in place on selected die to serve as die spacers in the use environment. Whether or not the spacers are temporary, the separated die may, for example, be individually mounted upon a support and electrically connected to circuitry in an environment for use.

Alternatively, the spacers may constitute a part of a completed and interconnected stacked die assembly. FIG. 1C shows at 6 a stack assembly as in FIG. 1B, having a vertical electrical interconnect 216 of an electrically conductive material contacting the respective interconnect terminals 40, 40′, 40″, 40′″, and thereby electrically connecting the interconnect pads on the respective die. The vertical interconnect 216 contacts the interconnect the terminal surfaces 113, 113′, 113″, 113′″ at the die edge, and the terminal surfaces 114, 114′, 114″, 114′″ at the die sidewall. As the FIGs. show, the interconnect material need not intrude into the space between adjacent die, as the terminals provide electrical continuity from the die pads to the interconnect die edges and over the interconnect die edges and the interconnect die sidewalls.

Suitable electrically conductive materials for the vertical electrical interconnect are applied in a flowable form, subsequently cured or permitted to harden. The vertical interconnect material may be an electrically conductive polymer; or a conductive ink. The vertical interconnect material may be a curable conductive polymer, for example, such as a curable epoxy; and the interconnect process may include forming traces of the uncured material in a prescribed pattern and thereafter curing the polymer to secure the electrical contacts with the pads and the mechanical integrity of the traces between them. The interconnect material is applied using an application tool such as, for example, a syringe or a nozzle or a needle. The material is applied by the tool in a deposition direction generally toward the lead ends at the sidewall surface, and the tool is moved over the presented die sidewall of die stack face in a work direction. The material may be extruded from the tool in a continuous flow, or, the material may exit the tool dropwise. In some embodiments the material exits the tool as a jet of droplets, and is deposited as dots which coalesce upon contact, or following contact, with the interconnect terminal surface. In some embodiments the deposition direction is generally perpendicular to the die sidewall surface, and in other embodiments the deposition direction is at an angle off perpendicular to the stack face surface. The tool may be moved in a generally linear work direction, or in a zig-zag work direction, depending upon the location on the die and on the substrate of the various pads to be connected.

Optionally, a plurality of deposition tools may be held in a ganged assembly or array of tools, and operated to deposit one or more traces of material in a single pass.

Alternatively, the material may be deposited by pin transfer or pad transfer, employing a pin or pad or ganged assembly or array of pins or pads.

The application of the material for the vertical interconnects may be automated; that is, the movement of the tool or the ganged assembly or array of tools, and the deposition of material, may be controlled robotically, programmed as appropriate by the operator.

Alternatively the material for the vertical interconnects may be applied by printing, for example using a print head (which may have a suitable array of nozzles), or for example by screen printing or using a mask. Various methods for forming the vertical electrical interconnects are described in, for example, U.S. patent application Ser. No. 12/124,097, referenced above.

As noted above, the interconnect terminal material is applied in an aerosol. Preferably, the terminal material is applied by aerosol jet printing. In aerosol jet printing the material is aerosolized and then entrained in a carrier as an aerodynamically focused droplet stream that can be directed through a nozzle onto a target surface. Suitable aerosol jet apparatus may include, for example, the M3D system, available from Optomec, Inc., Albuquerque, N. Mex. FIG. 2 shows a nozzle of an example of suitable aerosol jet apparatus, in a diagrammatic sectional view thru the nozzle axis. The nozzle 8 has a lumen 24 defined by an inner surface 22 of a generally tubular wall 20. An aerosol jet head (not shown in the FIG.) forms a flow of a sheath gas 25 surrounding a flow of aerosolized material 23. The flow of sheath gas and the entrained aerosolized material emerge from the tip 26 of the nozzle along a flow axis 27. The profile (that is, the shape in transverse section) and dimensions of the jet of aerosolized material can be controlled by selecting the dimensions of the nozzle lumen and by controlling the flow at various points around the flow axis. The jet profile may be generally circular, for example, or oval. The apparatus may be manipulated to direct the jet toward a target surface, and the target and the nozzle may be moved in relation to one another as indicated by the arrow 29 to form a line of material on the target surface.

FIGS. 3A-3C show a resulting line of material. In the example shown here, the profile of the jet has an elongated round shape, so that at any instant it would be expected to deposit the material in a corresponding shape as illustrated 32 in FIG. 3A. Movement of the nozzle tip over the target surface in a direction as illustrated by the arrow 39 in FIG. 3A forms a line 34, as shown in FIG. 3B, having a width w generally corresponding to the width of the jet profile. FIG. 3C shows a transverse sectional view of a deposited line of material 34 on a target surface 35, having a width w and a thickness t.

The profile of the jet may have a shape other than an elongated round shape. FIGS. 3D and 3E show a resulting line of material in an embodiment in which the jet has a generally circular shape, so that at any instant it would be expected to deposit the material in a corresponding shape as illustrated 36 in FIG. 3D. Movement of the nozzle tip over the target surface in a direction as illustrated by the arrow 39 in FIG. 3D forms a line 38, as shown in FIG. 3E, having a width w generally corresponding to the width (diameter) of the jet profile.

The thickness of the deposited line of material may in some embodiments range from as thin as about 10 nm or less to about 40 um or greater, usually in a range about 5 um to about 20 um, and in some particular embodiments about 10 um. The width of the deposited line of material may in some embodiments range from about 1 um or less to about 150 um or greater.

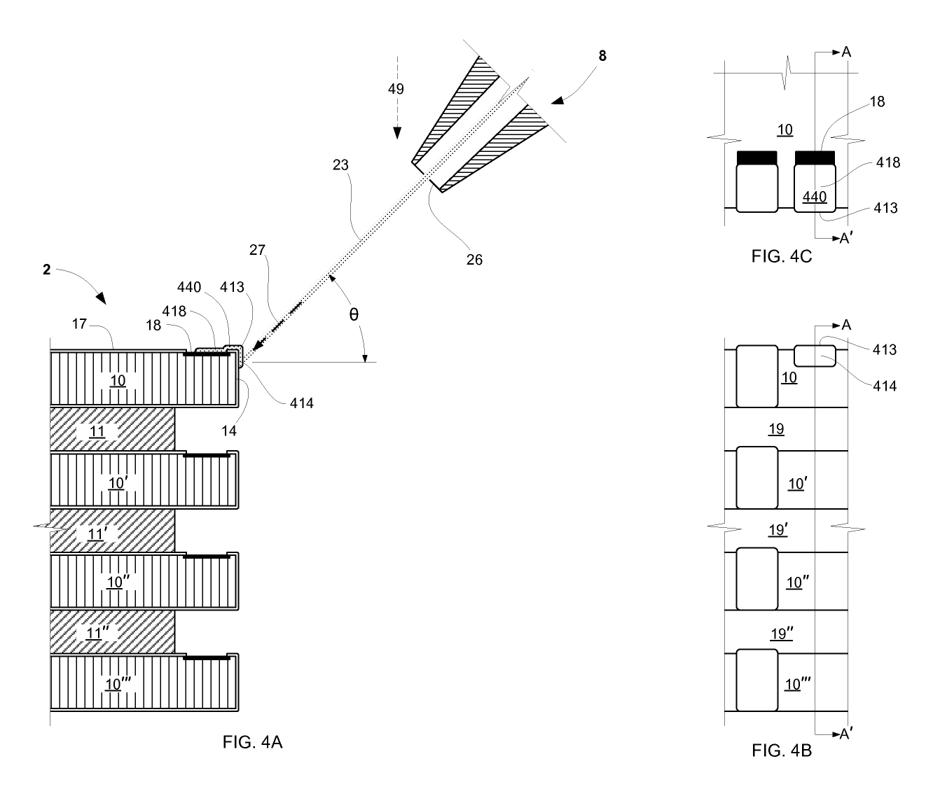

Stages in a procedure according to the invention for forming interconnect terminals on a stack of die as illustrated in FIG. 1A, with a result as illustrated in FIG. 1B, are shown in FIGS. 4A, 4B, 4C; 5A, 5B; and 6A, 6B. The FIGs. show a nozzle 8 generally as described with reference to FIG. 2, directing from the nozzle tip 26 a jet of aerosolized material 23 along a jet axis 27 toward a stack 2 of die as shown in FIG. 1A. The nozzle is being moved in a direction indicated by the arrow 49, so that it deposits a line of material onto the target surface of the die. The nozzle is positioned so that the jet axis 27 is at an angle θ with respect to the active sides of the die. FIG. 4A shows a stage at which the moving jet has left a line of deposited material (440) on the die 10: the line begins at 418 on the die pad 18, passes at 413 over the interconnect edge 13, and passes at 414 partway over the interconnect sidewall 14. The insulative conformal coating 17 prevents contact of the material with the die except at the pad 18, where the coating is opened to expose the pad. The interconnect margin of the die 10 is shown in a partial plan view in FIG. 4C, and the face of the stack of die 10, 10′, 10″, 10′″ is shown in a partial elevational view in FIG. 4B. In FIGS. 4C and 4B, a column of interconnect terminals is shown completed, and a subsequent column of interconnect terminal has been initiated to a stage shown in FIG. 4A; lines A-A′ indicate the sectional view of FIG. 4A.

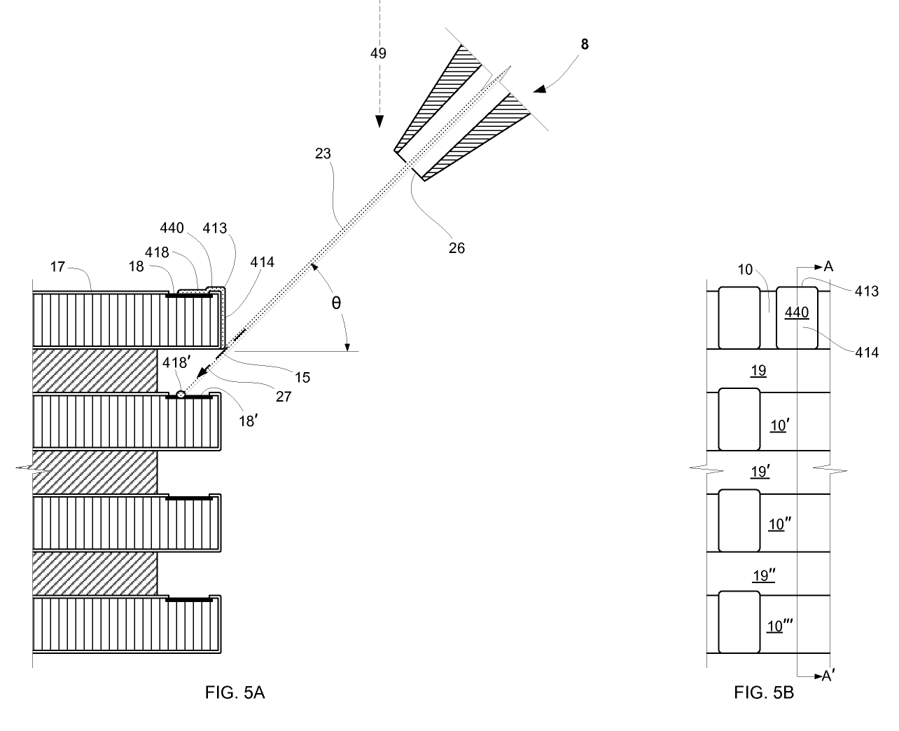

Later, as shown in FIG. 5A, as the nozzle is moved further along the trajectory 49 the jet passes the backside die edge 15 and begins to deposit material as shown at 418′ on the exposed pad 18′ on die 10′. The overhang of the die 10 provides a “shadow”, preventing deposit of material on the underlying die 10′ at points inboard of the spot 418′. As will be appreciated, the position of the spot where deposition starts on an underlying die will be determined by the angle θ and by the distance between the adjacent die in the stack, as established by the thickness of the spacer or of the die between them.

FIG. 5B shows the stack of FIG. 5A in a partial elevational view. The interconnect terminal 440 on die 10 has at this stage been completed, and the interconnect terminal on die 10′ does not yet appear in this view.

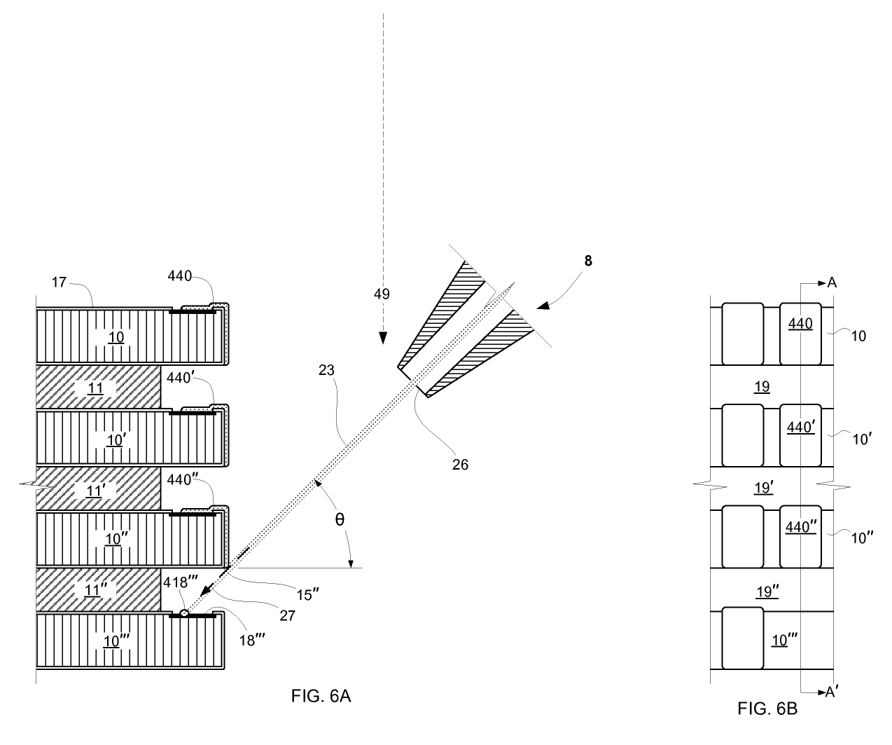

Still later, as shown at FIG. 6A, as the nozzle is moved further yet along the trajectory 49 the jet moves over the exposed target surfaces of die 10′ and die 10″ and begins to deposit material as shown at 418′″ on the exposed pad 18′″ on to die 10′″. The overhang of each die in the stack provides a “shadow”, preventing deposit of material on the respective adjacent underlying die at points inboard of the initial spot.

FIG. 6B shows the stack of FIG. 6A in a partial elevational view. Interconnect terminals 440 on die 10, 440′ on die 10′ and 440″ on die 10″ have at this stage been completed, and the interconnect terminal on die 10′″ does not yet appear in this view.

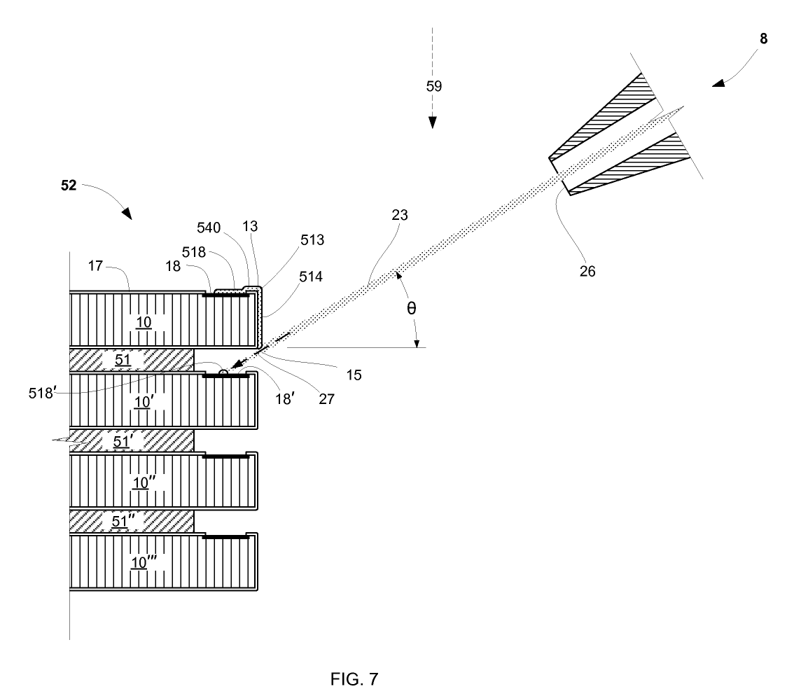

FIG. 7 illustrates a stack 52 of die 10, 10′, 10″, 10′″ separated by thinner spacers 51, 51′, 51″, at a stage in the deposition procedure similar to that shown in FIGS. 5A and 5B. FIG. 7 shows a stage at which the moving jet has left a line of deposited material (540) on the die 10: the line begins at 518 on the die pad 18, passes at 513 over the interconnect edge 13, and passes at 514 over the interconnect sidewall 14; the jet has passed the backside die edge 15 and has begun to deposit material as shown at 518′ on the exposed pad 18′ on die 10′. As described for the example above, the overhang of the die 10 provides a “shadow”, preventing deposit of material on the underlying die 10′ at points inboard of the spot 518′. As mentioned above, the position of the spot where deposition starts on an underlying die will be determined by the angle θ and by the distance between the adjacent die in the stack, as established by the thickness of the spacer between them. Because the distance between adjacent die in the stack here is smaller than in the example shown above, the nozzle must be positioned to direct the jet along an axis at a smaller angle with respect to the active sides of the die.

In the illustrations above, the nozzle is moved along a trajectory generally parallel to the plane of the active side of the die. In other embodiments the nozzle is moved along a trajectory generally perpendicular to the plane of the active side of the die. In still other embodiments the nozzle is moved along a trajectory that is at some other angle in relation to the plane of the active side of the die.

U.S. patent application Ser. No. 12/124,077, referenced above, describes stacked die units and stacked die assemblies in various embodiments having various stacking configurations. In some embodiments, for example, each die has interconnect pads situated in a margin along at least a first die edge, and succeeding die in the stack may be arranged so that their respective first die edges face toward the same face of the stack. This configuration presents as a “stairstep” die stack, and the interconnections are made over the steps. In other embodiments, for example, each die has interconnect margins along at least a first die edge, but succeeding die in the stack are arranged so that their respective first die edges face toward a different (e.g., opposite) face of the stack. Where the first die edges face toward an opposite stack face, this configuration presents as a “staggered” die stack, where (numbering the die sequentially from the bottom of the stack) the first die edges of odd-numbered die face toward one stack face and the first dies edges of even-numbered die face toward the opposite stack face. In a staggered stack, the first die edges of the odd-numbered die are vertically aligned at one stack face, and corresponding overlying pads can be connected by a vertical interconnect; and the even-numbered die are vertically aligned at the opposite stack face, and corresponding overlying pads can be connected by another vertical interconnect. In the staggered stack configuration the even-numbered die act as spacers between the odd-numbered die, and the odd-numbered die act as spacers between the even-numbered die. Because the spaces between the die are comparatively high, (approximately the thickness of the interposed die), the interconnect traces are formed to traverse portions of the interconnect distance unsupported. In still other embodiments, for example, die having an X-dimension greater than a Y-dimension are stacked, with succeeding die in the stack oriented at 90° in relation to vertically adjacent die below or above. In such embodiments each die has interconnect pads situated in a margin along at least a first narrower die edge (typically along both narrower die edges), and (numbering the die sequentially from the bottom of the stack) the first die edge of the even-numbered die may face toward one face of the stack, and the first die edge of the odd-numbered die may face toward a second stack face, at 90° to the first stack face. In any of these embodiments each die may additionally have interconnect pads situated in a margin along a second die edge in addition to the first, and the second die edge may be an opposite edge or an adjacent (at) 90° die edge.

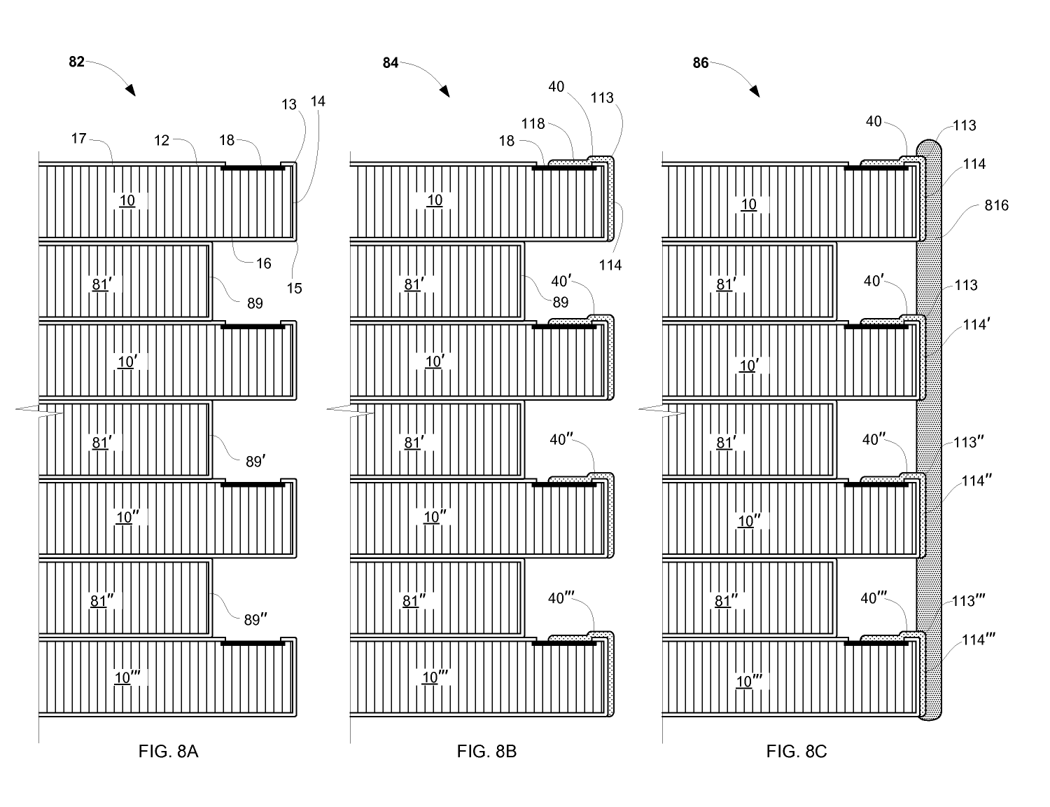

FIGS. 8A-8C illustrate at 82, 84, and 86 progressive stages in interconnection of the die in a stacked die assembly according to another embodiment of the invention. In this example, seven die 10, 81, 10′, 81′, 10″, 81″ and 10′″ are stacked over one another. As in the example shown in FIGS. 1A-1C, each die 10, 10′, 10″, 10′″, has an active (“front”) side 12, an opposite backside 16, and a sidewall 14. A front side die edge 13 is defined at the intersection of the front side 12 and the die sidewall 14, and a backside die edge 15 is defined at the intersection of the backside 16 of the die and the die sidewall 14. Interconnect pads, e.g. 18, are situated at the active side of the die 10, 10′, 10″, 10′″ in a margin of the die adjacent the front side die edge; accordingly die margin in which the pads are arranged may be referred to as an “interconnect margin”, the front side die edge may be referred to as an “interconnect edge”, and the die sidewall adjacent the interconnect edge may be referred to as an “interconnect sidewall”. The interconnect pads may be peripheral pads, and may be suitably arranged in the interconnect margin in the die as provided. Or, where the die as provided have center pads, or have peripheral pads in an undesirable arrangement, rerouting circuitry may be provided on the die, to provide for a suitable arrangement of the interconnect pads in a desired interconnect margin. Die 10, 10′, 10″, 10′″ in the stack are separated by interposed die 81, 81′, 81″, which may be dummy die, or which may be additional active die oriented differently from the die 10, 10′, 10″, 10′″ so that their respective interconnect sidewalls do not appear in the view shown here. That is, where the interposed die are active die, they may be rotated (for example, rotated 90° or 180° in relation to the die 10, 10′, 10″, 10′″. The interposed die are dimensioned and arranged so that the sidewalls 89, 89′, 89″, are recessed with respect to the interconnect sidewalls of the die 10, 10′, 10″, 10′″, leaving the die pads 18 uncovered. In embodiments where the interposed die are active die, the interconnect margins, interconnect edges and interconnect sidewalls of the interposed die 81, 81′, 81″ are not in view in these FIGs. The die are arranged in the stack so that the interconnect edges 13 of the die 10, 10′, 10″, 10′″ are positioned vertically generally (though not necessarily precisely) over one another, and so that the interconnect sidewalls 14 lie generally (though not precisely) in a plane generally perpendicular to the plane of the active side of any one of the die.

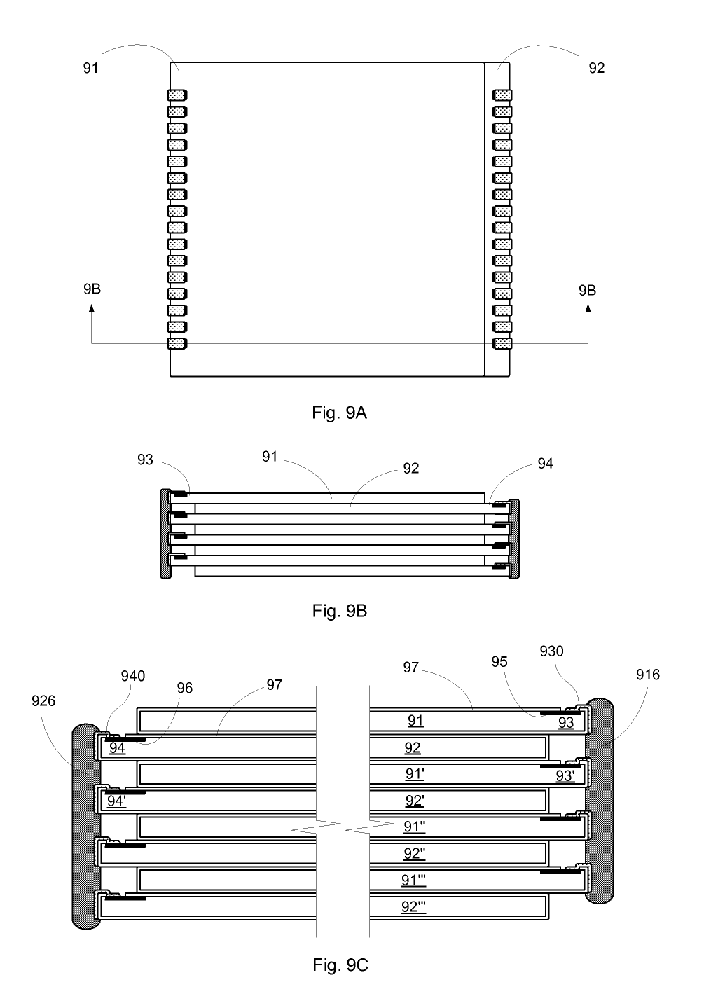

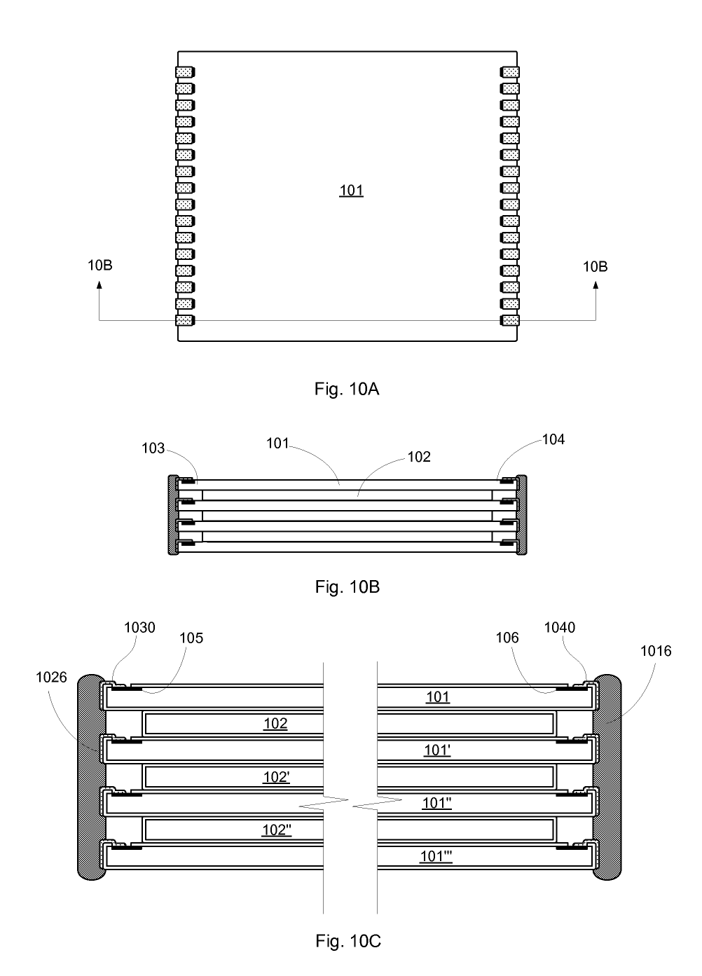

Such a stack may be referred to as a “staggered stack” of die, and various staggered stack configurations are illustrated in, for example, U.S. patent application Ser. No. 12/124,077, referenced above, and incorporated herein by reference. As may be appreciated, the interposed die in a “staggered stack” configuration may be interconnected according to the invention in a similar manner. FIGS. 9A, 9B, 9C illustrate a staggered stack arrangement. FIGS. 9A, 9B show an embodiment of a stacked die assembly, in which alternating die in the stack are mounted one over another so that respective interconnect edges are vertically aligned. In this configuration adjacent die in the stack, for example the uppermost two die 91, 92, are oppositely oriented (one is rotated 180° in relation to the other, so that the interconnect margins 93 and 94 are at opposite sides of the stack. The arrangement is shown in further detail in FIG. 9C. Referring now to FIG. 9C, die 91 is stacked over die 92. The interconnect margin 93 of die 91 is oriented toward the right in the FIG., and the interconnect margin 94 of die 92 is oriented toward the left. The die are offset so that the interconnect terminals of interconnect margin 94 are exposed. The interconnect pads 95, 96 are each provided with an interconnect terminal 930, 940, formed as described above, to provide contact access for traces or columns 916, 926 of interconnect material formed at the sides.

As FIG. 9C shows, each interconnect margin 93, 94 of the first pair of die 91, 92 overhangs the interconnect margin of the pair of die beneath; thus, for example, interconnect margins 93, 94 of die 91, 92 overhang interconnect margins 93′, 94′ of the next pair of die 91′, 92′. The configuration at each set of margins (left or right in the FIG.) is similar to that of the construct shown in FIG. 8C, in which the (even numbered) die 92, 92′, etc., serve as spacers for the (odd numbered) die 91, 91′, etc. Accordingly, the interconnect trace 926 provides electrical continuity between die 92, 92′, 92″, 92′″; and the interconnect trace 916 provides electrical continuity between die 91, 91′, 91″, 91′″.

In the example shown in these FIGs., each die is covered by a conformal electrically insulative coating 97, which may be formed of an organic polymer such as a parylene, for example.

As noted above, some die as provided have die pads on the front side along one or more of the die margins, and these may be referred to as peripheral pad die. Other die as provided have die pads arranged in one or two rows at the front side near the center of the die, and these may be referred to as center pad die. Where the die as provided have center pads, or have peripheral pads in an undesirable arrangement, rerouting circuitry may be provided on the die, to provide for a suitable arrangement of the interconnect pads in one or more desired interconnect margins. In the examples shown in FIGS. 9A-9C, for example, interconnect pads on each die are arranged in a die margin along one die edge. Where necessary the die as provided may be rerouted to provide this arrangement.

U.S. patent application Ser. No. 12/124,077, referenced above, shows embodiments of stacked die units or stacked die assemblies having various stacking configurations. In some embodiments, for example, each die has interconnect pads situated in a margin along at least a first die edge, and succeeding die in the stack may be arranged so that their respective first die edges face toward the same face of the stack. This configuration presents as a stairstep die stack, and the interconnections are made over the steps.

FIGS. 10A, 10B, 10C show an example of a stacked die assembly having a staggered configuration, in which interconnect pads on each die, e.g. die 101, are arranged in die margins 103, 104 along two opposite die edges, and here, too, the die as provided may be rerouted to provide this arrangement. In this embodiment, the die 101, 101′, 101″, 101′″ all have the same orientation in the stack, so that the interconnect margins 103 and 104 are at opposite sides of the stack. The die are stacked so that their interconnect edges are vertically aligned, and the die are separated by spacers 102, 102′, 102″. The arrangement is shown in further detail in FIG. 10C. Referring now to FIG. 10C, interconnect pads 105, 106 are each provided with an interconnect terminal 1030, 1040, formed as described above, to provide contact access for traces or columns 1016, 1026 of interconnect material formed at the sides.

The spacers 102, 102′, 102″ may be, for example, a film adhesive of suitable thickness both to fill the space and to affix the die to one another. Or, for example, the spacers may be interposed die, which may be dummy die, or which may be additional active die oriented differently from the die 101, 101′, 101″, 101′″ so that their respective interconnect sidewalls do not appear in the view shown here. The interposed die are dimensioned so that the die pads on the various die in the stack are left uncovered. That is, where the interposed die are active die, they may be rotated 90° in relation to the die 101, 101′, 101″, 101′″, and in such embodiments the interconnect margins, interconnect edges and interconnect sidewalls of the interposed die 102, 102′, 102″ are not in view in these FIGs. As will be understood the interconnect pads on the interposed die are provided with interconnect terminals, formed as described above, to provide contact access for traces or columns of interconnect material formed at those respective sides of the stack. The interposed die may optionally be covered with a thin dielectric film, as illustrated in FIG. 10C.

In the foregoing examples the stacked die assemblies are shown as being electrically interconnected one to another following formation of the interconnect terminals. As may be appreciated, in other embodiments the die may be temporarily stacked for the process of forming the interconnect terminals and, following completion of the terminals, the stack may be disassembled, resulting in a number of individual die each provided with interconnect terminals. The individual die may thereafter be further treated by, for example, mounting them individually onto and electrically connecting them to a support; or by, for example, stacking them in any desired stacked die configuration and electrically interconnecting the die in the stack and/or electrically connecting the stack to a support.

In the examples described above, the aerosol spray width constitutes the width of the interconnect terminal, and each line deposited by the aerosol spray constitutes an interconnect terminal (or a vertical series of interconnect terminals). In other examples, where the spray profile may be sufficiently wide, a mask-and-spray approach may be used to deposit two or more interconnect terminals at each pass of the spray tool. In such an approach, the spray profile width spans two or more adjacent interconnect pads on the die, and a patterned mask is used to prevent any deposition of the material that would result in undesirable electrical conduction between adjacent pads. The number of interconnect terminals that could be formed in each pass of the tool is limited by the maximum practicable spray width and upon the pitch of the interconnect pads. In principle it may be possible to form interconnect terminals along the full length of the die edge in a single pass of the tool.

In the foregoing examples interconnect terminals are formed on die using aerosol spray deposition of electrically conductive material. A stack of such die may be constructed, with vertically aligned interconnect sidewalls constituting an interconnect face of the stack, and the die may be electrically interconnected by forming traces or columns of electrically conductive interconnect material at the interconnect face of the die stack, in contact with the interconnect terminals. Similarly, electrical connection of a die or of a stack of die to circuitry on a substrate may be made by forming traces or columns of electrically conductive interconnect material, in contact with the interconnect terminals and with a site on the substrate.

In the examples following showing assemblies having die in a stack including offset stacked die in a stairstep configuration, electrical interconnection is made by using aerosol spray deposition to form interconnect traces contacting and running between die pads to be interconnected. In these embodiments a dielectric material is deposited to form a fillet at the inside angle (“inside corner”) formed by a die sidewall and a surface of an underlying feature (lower die, or substrate, for example), and the interconnect traces are formed over the fillet.

The dielectric material for the fillet may be selected as having thermal expansion characteristics that approximate or make a compromise between those of the various components of the assembly (die, substrate, die attach films, etc.), to help stabilize the assembly, reducing delamination effects. Suitable dielectric materials for the fillet can be deposited in a flowable form and thereafter cured or allowed to cure to form the fillet. Such materials include any of various polymers, particularly organic polymers, and they may include any of a variety of amendment components, such as fillers and the like. Particularly suitable materials include, for example, dielectric underfill materials. Underfill materials are employed commonly in semiconductor packaging applications and, accordingly, they have generally known mechanical, physical, and chemical characteristics from which an acceptable choice for the fillet can be made. They can be applied in a directed manner over a selected area using conventional tools. In the description following the material is described as an underfill material, it being appreciated that any suitable dielectric material may be employed.

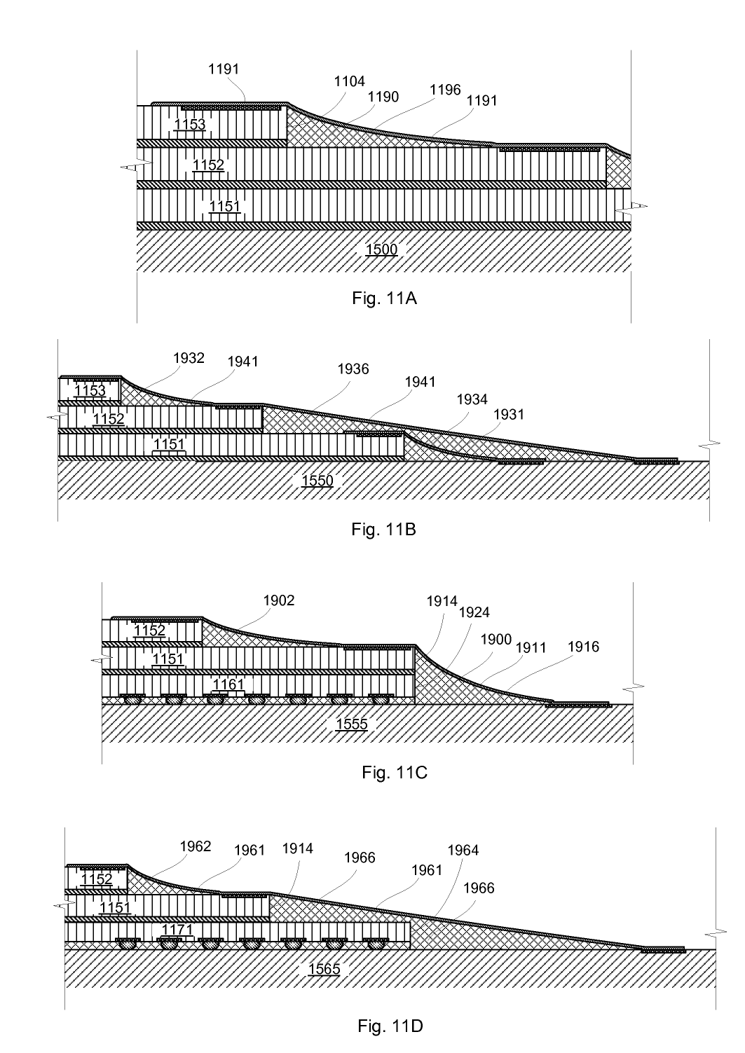

FIG. 11A illustrates a configuration in which the die sidewall is the interconnect sidewall 1104 of an upper die 1153, and the underlying surface is an electrically insulated area 1196 of the front side of an underlying die 1152, inboard of the die pads on the underlying die and adjacent the upper die sidewall. The deposited dielectric material (e.g., underfill material) forms a fillet 1190 which provides a gradually sloping surface extending from the upper die interconnect edge to the underlying die surface inboard from the die pads, on which an electrical interconnect trace 1191 can be formed, electrically connecting the pads on the upper die 1153 and the underlying die 1152 (and connecting additional die, e.g., die 1151 as appropriate) to circuitry in the substrate 1500. The electrical interconnect trace in this example is formed by aerosol spray deposition of electrically conductive material, as described above.

The dielectric (e.g., underfill) material may be deposited so that it forms a fillet approximating a right triangular shape in transverse section; viewed in this way the hypotenuse of the triangle shape is a sloping surface over which an interconnect trace can be formed; and a vertical side of the triangle forms an angle with the hypotenuse at or near the upper die interconnect edge. The sloping surface of the fillet may be slightly concave or convex, or may be a more complex slightly curved surface. The underfill material can have a CTE that approximates, or that constitutes a reasonably good compromise between, the CTEs of the various other components in the assembly, to help stabilize the assembly, reducing delamination effects. Moreover, the fillet, shaped as described above, can provide a gradual transition from die-to-die or from die-to-substrate, eliminating abrupt angular (approximately right-angle) transitions at the interconnect edges of the die and at the inside corners where the back edge of the die sidewall meets the underlying surface. In some configurations, a first fillet formed at the sidewall of a bottom die and a substrate can support a first set of electrical interconnect traces connecting pads on the bottom die with bond pads in a first row on the substrate; and an additional fillet formed over the first interconnect traces on the first fillet at the sidewall of an upper die and the bottom die can support a second set of interconnect traces from die pads on the upper die to bond pads in a second row, outboard from the first row, on the substrate.

A standard underfill material can be used to form the fillet, and it can be deposited using standard equipment for applying underfill. Preferred underfill materials may be high modulus materials, having thermal characteristics that are compatible with those of other materials in the assembly. By way of example, one suitable standard underfill material is marketed under the name Namics U8439-1.

The interconnect traces are substantially conformal to the surfaces upon which the interconnect material is deposited by the aerosol spray. Where no fillet is provided, for example, the trace would follow the die edges and die sidewalls and the adjacent surface of the underlying feature. In some configurations where the interconnects are very thin, cracks or breaks in the interconnects may appear following thermal stress at the “inside corner” where the backside edge of a die in the stack meets the surface of the underlying material.

As the illustrations show, where interconnect trace is formed over a fillet, abrupt corners are avoided in the surface over which the interconnect traces are formed. Particularly, for example, the surface of the fillet (for example, fillet 1190 in FIG. 11A) slopes gradually onto the surface of the underlying feature (for example, surface 1196 of underlying die 1152 in FIG. 11A). And, in these examples, the fillet meets the interconnect edge at the top of the upper die sidewall (for example, sidewall 1104 of die 1153 in FIG. 11A), so that the outside corner over which the interconnect trace passes at the interconnect edge of the upper die is significantly less than a right angle. Interconnect traces formed over such gradually contoured surfaces can be more robust and reliable than traces formed over abruptly angled surfaces, particularly where the traces are very thin.

FIG. 11B shows a further example, in which a fillet 1932 is formed at the inside angle formed between an interconnect sidewall of a die 1153 and a surface of an underlying die 1152; and a fillet 1934 is formed at the inside angle formed between an interconnect sidewall of a bottom die 1151 and a surface of the underlying substrate 1550. In this arrangement an interconnect trace 1931 is deposited on the fillet 1934 to connect the bottom die 1151 to a first row of bond pads on the substrate 1550; and thereafter a fillet 1936 is formed over the fillet 1934 and the trace 1931; and thereafter an interconnect trace 1941 is formed over the fillet 1932 and the fillet 1936 to connect the upper die 1153 to the die 1152 and to a second, outboard, row of bond pads on the substrate 1550.

FIG. 11C shows a configuration in which die 1151 and 1152 are mounted die-up over a flip-chip die 1161 mounted die-down on the substrate 1555, and in which a fillet 1900 is formed at the inside angle formed by sidewalls 1914, 1924 of the die 1151 and the flip chip die 1161 and the surface 1916 of the underlying substrate 1555 inboard from the bond pads. In this example an additional fillet 1902 is formed at the inside angles formed by the interconnect sidewall of the die 1152 and the surface of the underlying die 1151 inboard from the bond pads. The fillets 1900, 1902 provide a gradually sloping surface extending from the upper die 1152 interconnect edge to the underlying die surface inboard from the die pads, and then from the die 1151 interconnect edge to the underlying substrate surface inboard from the bond pads, on which an electrical interconnect trace 1911 can be formed, electrically connecting the pads on the upper die 1152 and the underlying die 1151 to circuitry in the substrate 1555.

In the example of FIG. 11C, the interconnect sidewall 1914 of die 1151 is shown as vertically aligned with the underlying sidewall 1924 of the underlying flip-chip die 1161. In other embodiments these features are not vertically aligned. By way of example FIG. 11D shows an embodiment in which the sidewall 1964 of the flip chip die 1171 projects beyond the sidewall 1914 of the overlying die 1151. A first fillet 1962 is formed at the inside angle formed between an interconnect sidewall of a die 1152 and a surface of an underlying die 1151. A second fillet 1966 is formed to fill the inside angles formed between the interconnect sidewall 1914 of the die 1151 and the projecting surface of the flip chip die 1171, and between the sidewall 1964 of the flip chip die 1171 and the surface of the underlying substrate 1565 inboard from the bond pads. The fillets 1966, 1962 provide a gradually sloping surface extending from the upper die 1152 interconnect edge to the substrate surface inboard from the bond pads, on which an electrical interconnect trace 1961 can be formed, electrically connecting the pads on the upper die 1152 and the underlying die 1151 to circuitry in the substrate 1555.

As noted above, the aerosol spray deposited interconnect material is substantially conformal with the surfaces on which it is deposited. Any such surfaces may make electrical contact with the conductive trace, except where the surfaces are electrically insulated. Accordingly it is to be understood that surfaces of the die that may contact the interconnect traces, and at which no electrical contact is desired, should be electrically insulated. This may be accomplished, for example, by applying a conformal dielectric film over the surfaces, and then forming openings in the film where electrical contact is desired. The dielectric film is not shown in any of FIGS. 11A-11D; suitable films are shown in other FIGs. herein. A particularly suitable dielectric film is a parylene film, and the film may be applied to the die prior to assembly in the stack; or after assembly but prior to forming one or more of the fillets; or at any time prior to forming one or more of the interconnect traces.

As may be appreciated, depositing the dielectric material in a controlled manner allows a good fillet surface profile over the surface inboard from the pads on the underlying feature, while avoiding a need to form openings through the fillet material to ensure exposure of the pads for electrical connection.

In forming interconnect terminals or interconnect traces by aerosol spray, an insufficient amount of material may be applied in a single pass of the spray tool. It may be desirable or necessary (depending upon the properties of the interconnect material and the parameters of the spray itself) to deposit the materials in two or more passes, to build up a sufficient amount. The spray tool may be moved in a first direction as a first pass, then in an opposite direction as a second pass. Or, the tool may be passed repeatedly in the same direction over the same path. As many as ten passes may be required, for example.

Where repeated passes are made, depending on physical characteristics of the material, subsequent passes may cause the deposit to widen as the material flows. In such circumstances it may be desirable to cure or partially cure the material following one or more passes and prior to subsequent pass; a cure or partial cure may be carried out following each pass or following a specified number of passes. Such a cure or partial cure may help to constrain the width of the resulting material deposit. The transverse profile of traces resulting from multiple passes may be thicker near the center than at the edges.

Where repeated passes are made, a greater mass of material may be deposited at the beginning and end points, and the material may spread to a greater trace width at these points—that is, the trace may bulge at these points. Too great a spread or bulge of the traces may increase the likelihood that adjacent traces may contact each other. To reduce the extent of such spread, where multiple passes are made in a given trace, the beginning and end points of the passes can be staggered. That is, not all the passes need begin and end at the same points along the trace. As a result, there may be two or more smaller bulges near the ends of a completed trace, rather than one large bulge; and the smaller bulges may not result in too great a trace width at those points. The passes need not begin at or near the center of a pad; where the pad is elongated in the direction of the trace various passes may begin at various points along the pad length. Moreover, the passes need not begin on a pad; they may begin inboard of a pad (for example on a die) or outboard of a pad (for example on the substrate).

Or, where repeated passes are made, the beginning and end points on adjacent traces may be staggered, so that the bulge[s] or spread[s] on one trace are located outboard or inboard from the bulge[s] or spread[s] on adjacent traces. In a simple example, the passes for each trace may begin and end at the end of the trace; and beginning and end of a trace may be inboard or outboard from the beginning and end of adjacent traces. As may be appreciated, some combination of staggering beginning and end points of the deposition passes and staggering the beginning and end points of the finished traces may be employed.

In the examples shown in FIGS. 11C and 11D a conventional underfill is shown as being additionally provided between the flip chip die and the substrate. The various dielectric materials employed in the fillet[s] and in the conventional underfill, where present, may be the same material, or they may constitute different materials. Such a conventional underfill may optionally be provided in a separate underfill dispense procedure. Or, alternatively, where the fillet next to the flip chip die is the same material as the conventional underfill, the underfill and the fillet may optionally be formed in an underfill dispense procedure by which the lower underfill fillet (1900 in FIG. 11C; 1966 in FIG. 11D) is formed.

The die in the stack may have the same or similar functionality, or one or more of them may have a functionality different from the others. For example, with reference to FIGS. 11C and 11D, the flip chip die may include a processor functionality, and the die stacked over it may be memory die. Other die combinations are contemplated.

Additional die may be stacked and provided with fillets and interconnected as described above.

As may be appreciated, the use of a fillet to provide a gradually contoured surface over which interconnect traces can be formed can be employed with die stack arrangements other than those illustrated by way of example in FIGS. 11A-11D. For instance, one or more of the die stacked over the lowermost die in the stack can be oriented differently than the lowermost die in the stack, and/or differently than other die stacked over the lowermost die.

All patent applications referred to herein are hereby incorporated herein by reference.

Other embodiments are included in the following claims.

What is claimed is:

1. A method for forming interconnect terminals on a plurality of die, each die having an active side, an interconnect margin and an interconnect sidewall adjacent an interconnect edge and having interconnect pads arranged in the interconnect margin, comprising
forming a stack of the die in which successive die in the stack are separated by spacers, and in which the die are arranged so that the interconnect sidewalls are situated generally in a plane perpendicular to the plane of the active side of the die and the spacers are offset in relation to the interconnect edges such that at least a portion of the interconnect margin is exposed; and
directing an aerosolized conductive material at a jet angle less than 90° and greater than 0° from the plane of the active sides of the die.

2. The method of claim 1 wherein, following formation of the interconnect terminals, the die are separated and individually treated.

3. The method of claim 1 wherein the die and spacers are further treated as a stacked die assembly.

4. The method of claim 1 wherein additional die constitute the spacers.

5. The method of claim 4 wherein the additional die are “dummy” die.

6. The method of claim 4 wherein the additional die are active die.

7. A method for forming interconnect terminals on an assembly of stacked die, each die having an active side, an interconnect margin and an interconnect sidewall adjacent an interconnect edge and having interconnect pads arranged in the interconnect margin, comprising
forming a stack of the die in which successive die in the stack are separated by spacers, and in which the die are arranged so that the interconnect sidewalls are all situated generally in a plane perpendicular to the plane of the active side of the die and the spacers are offset in relation to the interconnect edges such that at least a portion of the interconnect margin is exposed; and directing an aerosolized conductive material at a jet angle less than 90° and greater than 0° from the plane of the active sides of the die.

8. The method of claim 7 wherein additional die constitute the spacers.

9. The method of claim 7 wherein the additional die are “dummy” die.

10. The method of claim 7 wherein the additional die are active die.

11. The method of claim 10 wherein the additional die are arranged so that their interconnect sidewalls are all situated generally in a plane perpendicular to the plane of the active side of the die, and such that at least a portion of their interconnect margins are exposed.

12. The method of claim 10 wherein the additional die are provided with interconnect terminals by directing an aerosolized conductive material at a jet angle less than 90° and greater than 0° from the plane of the active sides of the additional die.

13. A method for making an electrically interconnected stacked die assembly, comprising
forming interconnect terminals on an assembly of stacked die, as set forth in claim 7, and
thereafter applying a trace of an electrically conductive interconnect material to connect interconnect terminals.

14. A plurality of die in a stack, each die having an active side, an interconnect margin and an interconnect sidewall adjacent an interconnect edge and having an interconnect pad in the interconnect margin, and having an interconnect terminal constituting a line formed from the pad to and over the interconnect edge and over the interconnect sidewall.

15. An assembly of stacked die, each die having an active side, an interconnect margin and an interconnect sidewall adjacent an interconnect edge and having interconnect pads arranged in the interconnect margin; the assembly including
a stack of the die in which successive die in the stack are separated by spacers, and in which the die are arranged so that the interconnect sidewalls are situated generally in a plane perpendicular to the plane of the active side of the die and the spacers are offset in relation to the interconnect edges; and
an interconnect terminal constituting a line formed from interconnect pads to and over the interconnect edge and over the interconnect sidewall.

16. A method for interconnecting offset die stack assemblies comprising
depositing a dielectric material at the inside angle formed by a die sidewall and an underlying surface to form a fillet; and forming an interconnect trace passing over the surface of the fillet.

17. The method of claim 16 wherein depositing the dielectric material to form the fillet comprises depositing an underfill material so that it forms a fillet having a sloping surface, wherein forming the interconnect trace comprises directing an aerosolized conductive material to form a line over the sloping surface of the fillet.

18. The method of claim 17 wherein depositing the dielectric material comprises forming a generally flat sloping surface.

19. The method of claim 17 wherein depositing the dielectric material comprises forming a slightly concave sloping surface.

20. The method of claim 17 wherein depositing the dielectric material comprises forming a slightly convex sloping surface.

21. The method of claim 17 wherein depositing the dielectric material comprises forming a complex slightly curved sloping surface.

22. The method of claim 16 wherein forming the interconnect trace comprises directing an aerosolized conductive material in a line contacting a first pad, passing over the surface of the fillet, and contacting a second pad to be electrically connected to the first pad.

23. The method of claim 22 wherein forming the interconnect trace comprises forming the line in a single pass.

24. The method of claim 22 wherein forming the interconnect trace comprises forming the line in two or more passes.

25. An electrically interconnected offset stacked die assembly, comprising
a die and an underlying feature, the die having an interconnect pad at an interconnect sidewall, the die sidewall and a surface of the underlying feature forming an inside angle;
a fillet at the inside angle formed by a die sidewall and the surface of the underlying feature, the fillet having a sloping surface; and
an interconnect trace contacting the pad and passing over the surface of the fillet.

26. The assembly of claim 25 wherein the sloping surface of the fillet is generally flat.

27. The assembly of claim 25 wherein the sloping surface of the fillet is slightly concave.

28. The assembly of claim 25 wherein the sloping surface of the fillet is slightly convex.

29. The assembly of claim 25 wherein the CTE of the fillet material approximates, or constitutes a reasonably good compromise between, CTEs of the material of one or more of the assembly components.

30. An electrically interconnected offset stacked die assembly, comprising
a substrate, a bottom die mounted on the substrate, and a first upper die;
a first fillet formed at a first inside angle formed by a sidewall of the bottom die and a surface of a substrate;
a first set of electrical interconnect traces connecting pads on the bottom die with bond pads in a first row on the substrate and passing over a sloping surface of the first underfill; and
a second fillet formed over the first interconnect traces on the first fillet and at a second angle formed by a sidewall of the first upper die and a surface of the bottom die inboard from the pads on the bottom die; and
a second set of electrical interconnect traces connecting die pads on the first upper die to bond pads in a second row, outboard from the first row, on the substrate.

31. The assembly of claim 30 wherein the bottom die sidewall comprises the interconnect sidewall of the bottom die.

32. The assembly of claim 30 wherein the surface of the substrate comprises an area of the die attach side of the substrate, inboard of the bond pads and adjacent the die sidewall.

33. An electrically interconnected offset stacked die assembly, comprising
a first die having a sidewall, and an underlying feature having a surface, the die sidewall and the surface meeting at a first inside angle;
a first fillet formed at the first inside angle; and
a first set of electrical interconnect traces contacting pads on the first die and passing over a sloping surface of the first fillet.

34. The assembly of claim 33 wherein the first die sidewall comprises an interconnect sidewall.

35. The assembly of claim 33 wherein the first die sidewall comprises an interconnect sidewall of an upper die.

36. The assembly of claim 33 wherein the surface on the underlying feature comprises an electrically insulated area of a front side of an underlying die, inboard of die pads on the underlying die and adjacent the first die sidewall.

37. The assembly of claim 33 wherein the underlying feature comprises a substrate and the first die sidewall comprises a sidewall of a flip chip die oriented die-down on the substrate, the flip chip die being electrically connected to circuitry in the substrate within the die footprint.

38. The assembly of claim 37 wherein the surface of the underlying feature comprises an electrically insulated area of the die attach side of the substrate, inboard of bond pads on the substrate and adjacent the die sidewall.

39. The assembly of claim 33 wherein the underlying feature comprises a flip chip die and the first interconnect sidewall comprises an interconnect sidewall of a die stacked over the flip chip die.

40. The assembly of claim 33 wherein the underlying feature comprises a flip chip die and surface of the underlying feature comprises can be an electrically insulated area of the back side of the underlying flip chip die.

41. The assembly of claim 33 wherein the interconnect trace is formed by directing an aerosolized conductive material in a line contacting a pad on the first die, passing over the surface of the fillet, and contacting a second pad to be electrically connected to the first pad.
